(19) United States
(12) Patent Application Publication
(10) Pub. No.: US 2026/0314360 A1
(43) Pub. Date: Oct. 8, 2026

(54) METHODS AND SYSTEMS FOR AREA SELECTIVE PROCESSING

(71) Applicant: Tokyo Electron Limited, Tokyo (JP)

(72) Inventor: Kandabara Tapily, Albany, NY (US)

(21) Appl. No.: 19/171,818

(22) Filed: Apr. 7, 2025

(51) Int. Cl. H10W 20/00

(52) U.S. Cl. CPC H10W 20/074; H10W 20/092

(57) ABSTRACT

A method is provided for processing a substrate. The method includes providing a substrate including a first region and a second region, wherein the first region includes a catalytic surface and the second region includes a non-catalytic surface. A polymer layer is selectively formed over the catalytic surface of the first region. A coating layer is formed over the polymer layer and the second region. The coating layer is planarized to expose the polymer layer. The polymer layer is removed by annealing the substrate.

### TECHNICAL FIELD

The present invention relates generally to a system and method for semiconductor fabrication, and, in particular embodiments, to area selective processing.

### BACKGROUND

Generally, semiconductor devices, such as integrated circuits (ICs), are fabricated by sequentially depositing and patterning layers of dielectric, conductive, and semiconductor materials over a semiconductor substrate. Photolithography and etching processes are employed to form structures that operate as circuit components (e.g., transistors, resistors, and capacitors) and as interconnect elements (e.g., conductive lines, contacts, and vias). The semiconductor industry continuously advances toward higher integration density by reducing minimum feature size, enabling more components to be integrated into a given area. This scaling trend has led to increasingly complex fabrication challenges, particularly in the formation of precisely aligned features at nanometer dimensions.

In conventional semiconductor manufacturing, multiple lithography and etch steps are required to create patterns for interconnects and other device structures. These processes typically involve depositing a blanket film, applying photoresist, exposing the resist through a mask, developing the pattern, etching the underlying film, and removing the resist. As feature sizes decrease, this approach faces significant challenges related to overlay accuracy, edge placement error, and process variation. These challenges often necessitate additional processing steps and more sophisticated equipment, substantially increasing manufacturing complexity and cost.

### SUMMARY

In accordance with one aspect of the present invention, a method is provided for processing a substrate. The method includes providing a substrate comprising a first region and a second region, wherein the first region comprises a catalytic surface and the second region comprises a non-catalytic surface. A polymer layer is formed selectively over the catalytic surface of the first region. A coating layer is formed over the polymer layer and the second region. The coating layer is planarized to expose the polymer layer. The polymer layer is removed by annealing the substrate.

In accordance with another aspect of the present invention, a method is provided for processing a substrate. The method includes loading a substrate in a process chamber, the substrate comprising a first region comprising a metal surface and a second region comprising a non-catalytic surface. A catalytic metal cap is formed over the metal surface of the first region. A polymer layer is deposited selectively over the catalytic metal cap. A coating layer is formed over the polymer layer and the second region. The coating layer is planarized to expose the polymer layer. The polymer layer is removed by annealing the substrate.

In accordance with yet another aspect of the present invention, a system is provided for processing a substrate. The system includes a transfer module configured to maintain vacuum conditions. A surface treatment module is coupled to the transfer module and configured to apply a surface treatment material to a substrate. A metal cap module is coupled to the transfer module and configured to form a catalytic metal cap on the substrate. A polymer deposition module is coupled to the transfer module and configured to selectively deposit a polymer layer on the catalytic metal cap. A planarization module is coupled to the transfer module and configured to planarize the substrate. An annealing module is coupled to the transfer module and configured to remove the polymer layer from the substrate.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1I illustrate cross-sectional views of a process flow for area selective processing using an embedded catalytic metal, in accordance with one embodiment;

FIGS. 2A-2I illustrate cross-sectional views of a process flow for area selective processing using a deposited catalytic metal cap, in accordance with one embodiment;

FIGS. 3A-3H illustrate cross-sectional views of a process flow for applying area selective processing to a three-dimensional structure, in accordance with one embodiment;

FIG. 4 illustrates a flow chart of a method for area selective processing using an embedded catalyst metal, in accordance with one embodiment;

FIG. 5 illustrates a flow chart of a method for area selective processing using a deposited catalytic metal cap, in accordance with one embodiment; and

FIG. 6 illustrates a schematic diagram of an integrated system for in-situ processing of area selective processing, in accordance with one embodiment.

### DETAILED DESCRIPTION OF ILLUSTRATIVE EMBODIMENTS

Self-aligned patterning techniques, particularly area selective deposition (ASD), have emerged as promising solutions for cost-effective scaling. These techniques allow materials to be deposited only on specific surfaces while preventing deposition on others, thereby reducing process complexity and improving device performance. However, implementation of ASD in high-volume manufacturing faces significant challenges. Conventional ASD approaches often suffer from stability degradation of blocking layers when exposed to deposition chemistries, leading to selectivity loss and defect formation. Additionally, conventional methods for removing unwanted materials involve etching processes that may damage underlying surfaces, compromising device integrity.

The present disclosure introduces a catalytic polymer removal process following area selective deposition. In various embodiments, a sacrificial polymer layer may be selectively disposed on catalytic metal surfaces. After polymer deposition, dielectric or metal materials may be deposited over the entire surface which may be then planarized to expose the underlying polymer layer. Afterwards, the polymer layer may be removed through an annealing step, where a catalytic oxidation reaction may happen at the catalytic metal surfaces to convert oxygen-containing molecular species to a reactive species that efficiently remove the polymer.

The catalytic polymer removal process may avoid harsh chemicals and aggressive plasma conditions used in conventional etching process that might introduce contamination or surface roughening. Additionally, the catalytic nature of the process provides inherent selectivity, as the polymer removal may occur preferentially at the catalytic interface, allowing for precise pattern formation without the need for additional masking steps or complex etch chemistries. Moreover, the sacrificial polymer layer may provide high tolerance for polymer defects. Even if the polymer contains imperfections such as pinholes or thickness variations during deposition, these defects may not propagate to the final structure since the polymer is completely removed during catalytic oxidation. These advantages may enhance manufacturing yield and reduce quality requirements for the polymer deposition step, making the process well-suited for high-volume semiconductor manufacturing.

The disclosed methods may be particularly suitable for applications including fully self-aligned via (FSAV), self-aligned gate contact (SAGC), ASD of spacers, and other patterning applications such as dielectric-on-dielectric selective deposition. In addition, the process may be performed in a single integrated platform, allowing for in-situ deposition and removal steps that reduce contamination risks and processing time, thereby enhancing manufacturing yield and device performance.

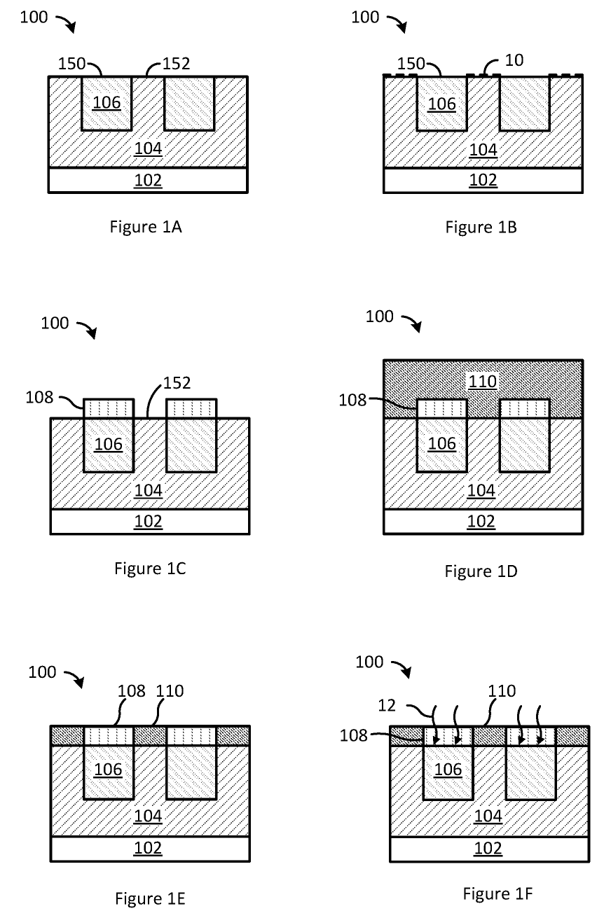

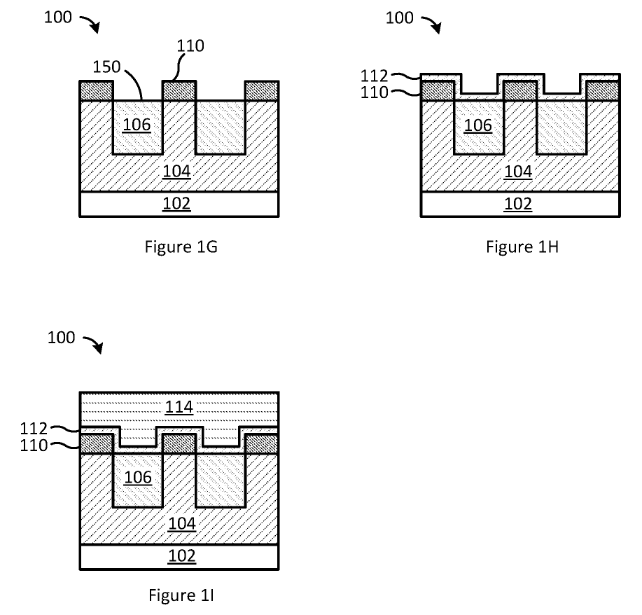

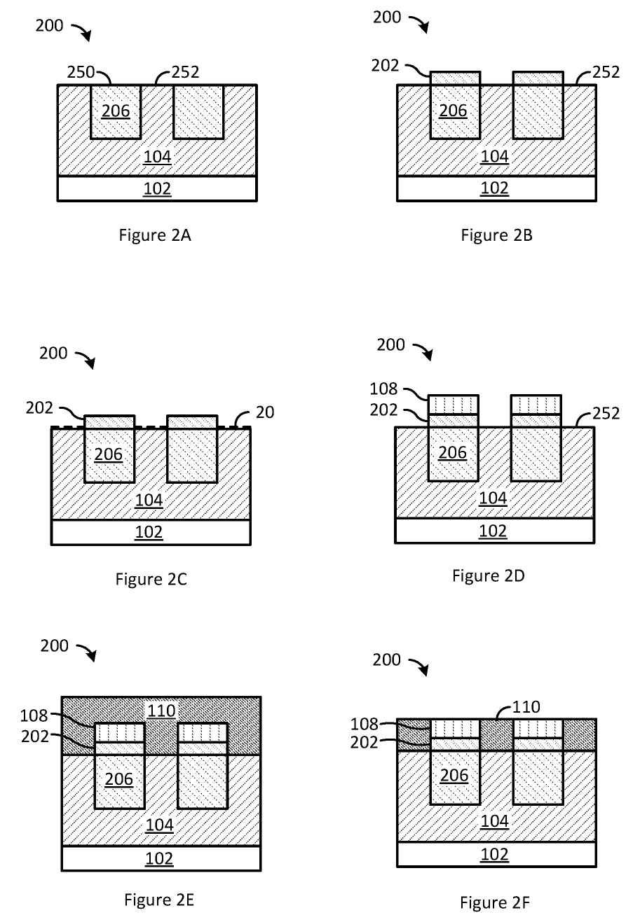

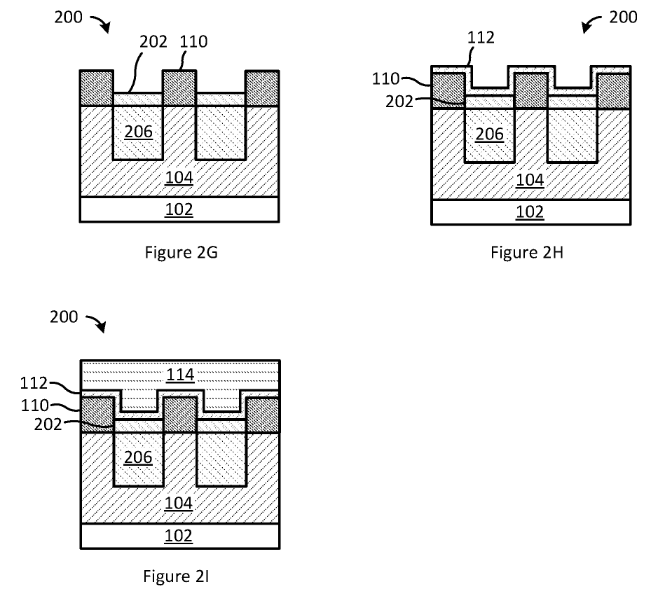

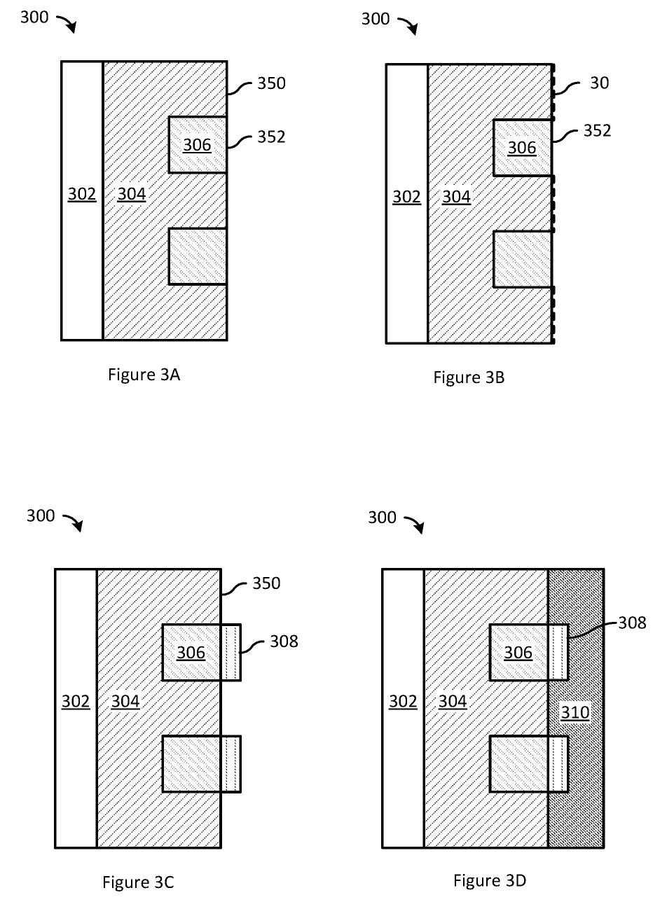

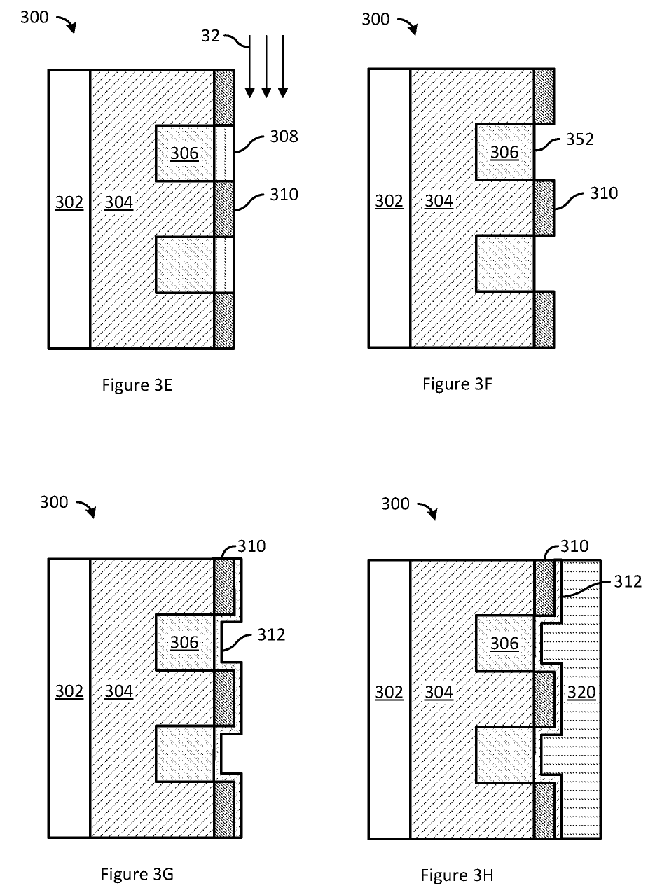

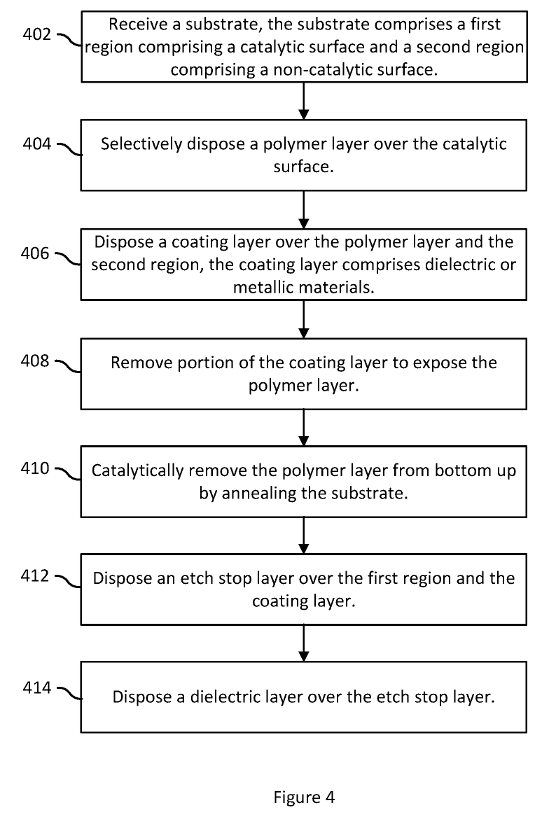

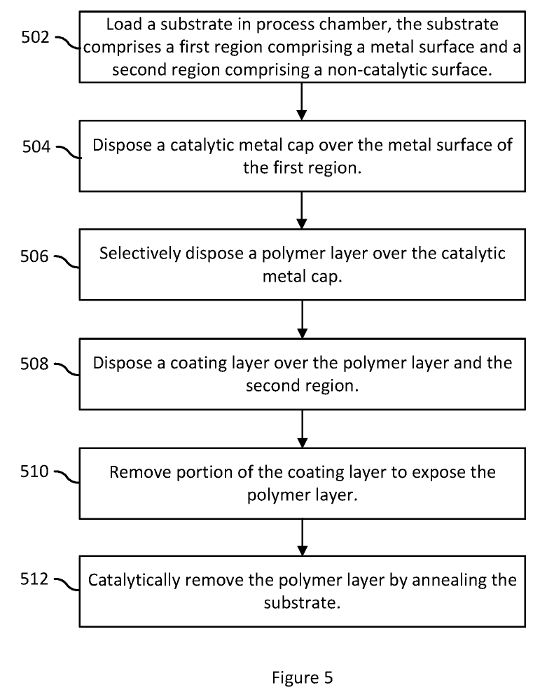

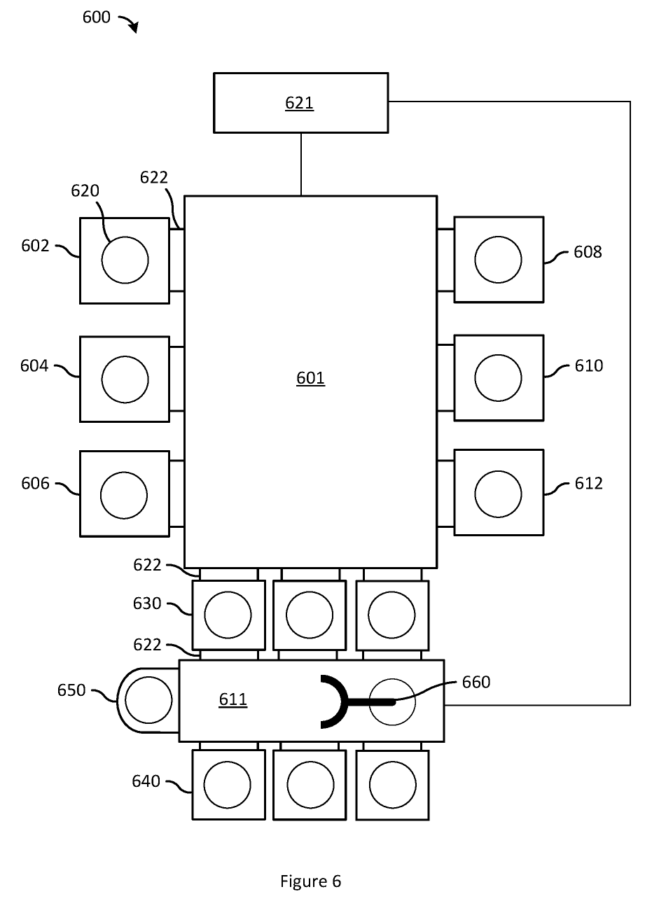

Embodiments of the disclosure are described in the context of the accompanying drawings. A process flow for area selective processing using an embedded catalyst metal is illustrated in FIGS. 1A-1I. An embodiment showing a process flow with a deposited catalytic metal cap is described in FIGS. 2A-2I. An embodiment demonstrating the application of the area selective processing technique to a three-dimensional structure is presented in FIGS. 3A-3H. A process flow diagram for an embodiment with embedded catalyst metal is shown in FIG. 4. A process flow diagram for an embodiment with deposited catalytic metal cap is illustrated in FIG. 5. An integrated system for in-situ processing of area selective processing is depicted in FIG. 6.

FIGS. 1A-1I illustrate cross-sectional views of process steps for area selective processing on a substrate, in accordance with one embodiment.

FIG. 1A illustrates a cross-sectional view of a substrate 100 comprising a first region 106 and a second region 104. The first region 106 may comprise a catalytic surface 150, while the second region 104 may comprise a non-catalytic surface 152. Both the first and the second regions 106 and 104 may be disposed over a substrate layer 102. The catalytic surface 150 may facilitate reactions by lowering the activation energy barriers without being consumed. For example, certain metals can promote the conversion of molecular oxygen or molecular hydrogen into reactive species such as atomic species. The non-catalytic surface 152, in contrast, will not lower reaction barriers although they might participate in reactions such as oxidation.

In various embodiments, the first region 106 with the catalytic surface 150 may comprise metals such as ruthenium (Ru), platinum (Pt), palladium (Pd), cobalt (Co), or other transition metals that exhibit catalytic properties. The catalytic surface 150 may enable selective polymer deposition and removal in subsequent processing steps.

In one or more embodiments, the first region 106 may comprise a thin catalytic metal layer at its top surface, such as ruthenium (Ru), platinum (Pt), cobalt (Co), or palladium (Pd), while the bulk of the region comprises metals commonly used in semiconductor interconnects, such as aluminum (Al), copper (Cu), molybdenum (Mo), or tungsten (W). In various embodiments, the catalytic metal layer may be as thin as 1-5 nanometers while still providing sufficient catalytic activity for selective polymer deposition and removal.

In another embodiment, the first region 106 may be an alloy of catalytic metals and non-catalytic metals, such as ruthenium-copper alloy, platinum-aluminum alloy, or cobalt-tungsten alloy, where the catalytic metal is distributed throughout the volume of the first region 106 but present in sufficient concentration at the surface. These alloy structures can be engineered to optimize both catalytic activity and electrical performance, with catalytic metal concentrations ranging from 2% to 50% depending on the specific metals involved and the desired catalytic efficiency.

In one or more embodiments, the second region 104 with non-catalytic surface 152 may comprise dielectric materials such as silicon dioxide (SiO₂), silicon nitride (SiN), silicon oxynitride (SiOₓC_{y}N_{z}) where 0≤x≤1, 0≤y≤1, 0≤z≤1, or low-k dielectric materials. The second region 104 may isolate different first regions 106 from electrical contacts.

In one or more embodiments, a structure of the first and the second regions 106 and 104 may represent an interconnect structure where metal lines are embedded in a dielectric material. For example, the first region 106 may be a metal line comprising a catalytic metal such as ruthenium that is embedded within a dielectric material forming the second region 104. The metal line may serve as a capping layer for an underlying copper interconnect or as a standalone interconnect line.

In various embodiments, the substrate layer 102 may comprise silicon, silicon-on-insulator (SOI), or other semiconductor materials suitable for integrated circuit fabrication. In various embodiments, the substrate layer 102 may also include previously formed device structures such as transistors, capacitors, or lower-level interconnect structures.

FIG. 1B illustrates a cross-sectional view of a surface treatment process applied to the substrate 100, in accordance with one embodiment. A surface treatment material 10 may be selectively applied to the non-catalytic surface 152 of the second region 104 before subsequent polymer deposition. This treatment may serve to further inhibit polymer growth over the non-catalytic surface 152 during subsequent processing steps.

In various embodiments, the surface treatment material 10 may comprise phosphonic, carboxyllic, amine, silane inhibitor molecules such as trimethylsilyldimethylamine (TMSDMA), which may selectively adhere to the non-catalytic surface 152. In one or more embodiments, the surface treatment material 10 may also comprise other silanes such as hexamethyldisilazane (HMDS), bis(dimethylamino)dimethylsilane (DMADMS), trimethylchlorosilane (TMCS), octadecyltrichlorosilane (OTS), dimethyldichlorosilane (DMDCS), or the like. These silane-based materials may form self-assembled monolayers on the non-catalytic surface 152, creating a chemical barrier that inhibits subsequent polymer deposition.

In various embodiments, the surface treatment material 10 may be applied using various techniques including vapor phase deposition, liquid phase deposition, or plasma-enhanced deposition. In an embodiment, the surface treatment process may be performed at temperatures ranging from room temperature to approximately 400 °C, with process time ranging from a few seconds to several minutes depending on the specific silane compound.

In various embodiments, selective adhesion of the surface treatment material 10 to the non-catalytic surface 152 may occur due to the chemical affinity between the silane compounds and the surface materials. For example, when the non-catalytic surface 152 comprises silicon dioxide or other oxide materials, the silane compounds react with hydroxyl groups on the oxide surface to form covalent bonds, creating a well-adhered monolayer.

This surface treatment step may enhance the selectivity of the subsequent polymer deposition by creating a contrast between the catalytic surface 150, which remains reactive for polymer growth, and the non-catalytic surface 152, which has reduced reactivity due to the presence of the surface treatment material 10. The combination of inherent surface property differences and the surface treatment material 10 may enable highly selective polymer deposition in subsequent processing steps.

In various embodiments, the non-catalytic surface 152 may also be treated with alternative methods to enhance selectivity. In one or more embodiments, plasma treatment using gases such as hydrogen, nitrogen, argon, or oxygen may be employed to modify the surface properties of the non-catalytic surface 152, altering its reactivity toward polymer precursors. In alternative embodiments, thermal annealing in controlled atmospheres (e.g., forming gas, nitrogen, or vacuum) at temperatures between 200 °C and 400 °C may also be used to dehydroxylate the surface or induce surface reconstruction that inhibits polymer nucleation. In one or more embodiments, optical treatments using ultraviolet (UV) light or laser irradiation may be applied to create photochemical modifications to the non-catalytic surface 152, selectively changing its chemical functionality. These alternative treatment methods may be used independently or in combination with the surface treatment material 10 to achieve optimal selectivity between the catalytic surface 150 and non-catalytic surface 152.

In FIG. 1C, a polymer deposition process may be applied to the substrate 100, in accordance with one embodiment. A polymer layer 108 may be selectively disposed over the catalytic surface 150 of the first region 106.

In various embodiments, the polymer layer 108 may comprise polymers such as nylon, polyaniline (PANI), polypyrrole (PPY), or polyethylenedioxythiophene (PEDOT). The polymer layer 108 may exhibit selective deposition due to its ability to undergo oxidative polymerization in the presence of catalytic metals. In one or more embodiments, the polymer layer 108 may also comprise polythiophene, polyacetylene, poly(p-phenylene vinylene), or derivatives thereof, which may also exhibit selective growth behavior on catalytic surfaces.

In various embodiments, the polymer layer 108 may be deposited with a thickness ranging from 1 to 30 nm, with the specific thickness selected based on the requirements of subsequent processing steps. In one or more embodiments, the polymer layer 108 may form a functionalized 2D polymer structure that is impermeable for molecular diffusion of species such as oxygen.

In one embodiment, deposition of the polymer layer 108 comprising PEDOT may involve the use of 3,4-ethylenedioxythiophene (EDOT) monomers with additives such as antimony pentachloride (SbCl₅) or molybdenum pentachloride (MoCl₅) that serve as polymerization catalysts. The deposition chamber may be maintained at approximately 150 °C, e.g., 80 °C to 250 °C, during the polymerization process to optimize reaction kinetics and polymer film properties. These conditions promote the formation of highly ordered PEDOT chains with excellent stability.

In various embodiments, the polymer layer 108 may be selectively deposited using molecular layer deposition (MLD) methods, which provide precise thickness control and conformality through sequential, self-limiting surface reactions that build up the polymer chain one molecular layer per reaction cycle. In alternative embodiments, the polymer layer 108 may be deposited with vapor phase polymerization (VPP), where monomer vapors and oxidizing agents are introduced sequentially or simultaneously to the substrate surface. In additional embodiments, solution-based selective deposition may be utilized, wherein the substrate 100 may be immersed in or exposed to a solution containing monomers and oxidizing agents that preferentially react at the catalytic surface 150. In other embodiments, electrochemical deposition may be used, particularly for conductive polymers, where an applied potential drives the polymerization reaction selectively on conductive catalytic surfaces. In more embodiments, plasma-enhanced chemical vapor deposition (PECVD) with appropriate precursors may also be employed to achieve selective polymer growth on the catalytic surface 150.

In various embodiments, the selective nature of the polymer deposition occurs because the catalytic surface 150 may facilitate the polymerization reaction by lowering activation energy barriers and providing active sites for polymer chain initiation and propagation. Meanwhile, the treated non-catalytic surface 152 may remain inactive toward the polymerization reaction due to both its inherent non-catalytic properties and the presence of the surface treatment material 10, which further inhibits polymer nucleation and growth.

FIG. 1D illustrates a cross-sectional view of a coating layer deposition process. In various embodiments, a coating layer 110 may be disposed over both the polymer layer 108 and the second region 104. In various embodiments, the coating layer 110 may be deposited using various techniques including atomic layer deposition (ALD), chemical vapor deposition (CVD), or physical vapor deposition (PVD).

In one or more embodiments, the coating layer 110 may comprise dielectric materials such as silicon dioxide (SiO₂), silicon nitride (SiN), silicon oxynitride (SiON), silicon carbide (SiC), or low-k dielectric materials. In alternative embodiments, the coating layer 110 may comprise metallic materials such as tungsten (W), titanium (Ti), titanium nitride (TiN), tantalum (Ta), tantalum nitride (TaN), or other metals and metal compounds commonly used in semiconductor manufacturing. The selection of specific materials for the coating layer 110 depends on the intended application and subsequent device requirements.

In some embodiments, the surface treatment material 10 may be removed before depositing the coating layer 110. This removal step may be accomplished through techniques such as plasma treatment, thermal annealing, or chemical cleaning. In many embodiments, the removal of the surface treatment material 10 may enhance adhesion between the coating layer 110 and the non-catalytic surface 152, improving the mechanical stability.

FIG. 1E illustrates a cross-sectional view of a planarization process, in accordance with one embodiment. The coating layer 110 may be planarized to expose the underlying polymer layer 108 while maintaining the coating layer 110 over the second region 104. The planarization process may create a flat surface where the top of the polymer layer 108 and the remaining coating layer 110 are coplanar, establishing a well-defined pattern for subsequent selective material removal.

In various embodiments, the planarization may be performed using chemical mechanical planarization (CMP) techniques, etch back, or a combination of thereof. The CMP techniques may combine chemical etching and mechanical abrasion to remove material and create a planar surface. Slurry compositions used during CMP may be tailored to provide appropriate selectivity between the coating layer 110 and the polymer layer 108, allowing the process to effectively stop when the polymer layer 108 is exposed. Endpoint detection systems, such as optical reflectance monitoring or friction coefficient measurement, may be employed to precisely determine when the polymer layer 108 is reached. The CMP process parameters, including down force, rotational speed, slurry composition, and processing time, are optimized based on the specific materials of the coating layer 110 and polymer layer 108 to achieve uniform material removal across the substrate.

In alternative embodiments, the planarization may be accomplished through etching processes rather than CMP. Reactive ion etching (RIE) may be employed with appropriate gas chemistries that provide controlled etch rates and adequate selectivity between the coating layer 110 and the polymer layer 108. In some embodiments, fluorocarbon-based plasma etching may be used for dielectric coating layers, while chlorine-based or fluorine-based chemistries may be used for metallic coating layers. In other embodiments, atomic layer etching (ALE) techniques may be applied for highly controlled layer-by-layer removal of the coating layer 110 until the polymer layer 108 is exposed. Wet etching methods using selective chemical solutions may also be utilized, particularly when the coating layer 110 and polymer layer 108 exhibit significant differences in their chemical reactivity. In some implementations, a combination of etching techniques may be employed, such as a main etch step followed by a highly selective final etch step to minimize damage to the exposed polymer layer 108.

In various embodiments, an etch back process may be utilized for planarizing the coating layer. The etch back process involves depositing the coating layer 110 to a thickness greater than required, followed by a blanket etching process that uniformly removes material across the substrate surface until the polymer layer 108 is exposed. Unlike directional etching used for pattern transfer, the etch back process may employ more isotropic etching conditions to achieve uniform material removal rates across the substrate. The etch back may be performed using plasma etching with carefully controlled gas mixtures, pressures, and power settings to achieve uniform etching rates. In some embodiments, a sacrificial planarizing layer such as photoresist or spin-on glass may be applied over the coating layer 110 before etching to enhance planarization efficiency. The sacrificial layer and coating layer may be then etched at similar rates, transferring the planar surface to the underlying materials and exposing the polymer layer 108. The etch back approach may be particularly advantageous for substrates with varying pattern densities or when CMP processes might cause dishing or erosion in certain regions.

In one or more embodiments, a combination of CMP and etch back processes may be employed for optimal planarization results. This hybrid approach may involve an initial CMP step to remove the bulk of the coating layer 110, followed by a controlled etch back process to expose the polymer layer 108 with minimal damage or topographical variation. The combination may leverage the rapid material removal capability of CMP while utilizing the uniform and controlled nature of etch back for the final exposure step.

In FIG. 1F, the polymer layer 108 may be removed through a catalytic oxidation process by annealing the substrate 100 (or referred to as a catalytic polymer removal process). In various embodiments, the polymer layer 108 may be removed by annealing the substrate 100 in an oxygen ambient at a temperature less than 400 °C. This thermal annealing process may facilitate the selective removal of the polymer layer 108 while leaving the coating layer 110 and the catalytic surface 150 intact.

In various embodiments, oxygen molecules 12 from the ambient atmosphere may diffuse through the polymer layer 108 to reach the interface between the polymer layer 108 and the catalytic surface 150 of the first region 106. At this interface, the catalytic metal may facilitate conversion of molecular oxygen (O₂) to more reactive oxygen species such as ozone (O₃) or atomic oxygen (O). These reactive oxygen species may efficiently oxidize the polymer from the bottom up, breaking down the polymer chains into volatile compounds that can diffuse out of the structure.

In one or more embodiments, instead of annealing in an oxygen ambient atmosphere, the substrate 100 may be annealed in an inert ambient comprising oxygen-containing precursors, nitrogen, argon, or helium. In various embodiments, the oxygen-containing precursors may comprise water vapor (H₂O), hydrogen peroxide (H₂O₂), nitrous oxide (N₂O), or carbon dioxide (CO₂), which may serve as oxygen sources that decompose at the catalytic surface 150 to generate reactive oxygen species for polymer removal.

The catalytic polymer removal process may exhibit several advantages compared to conventional etching processes. First, it eliminates the potential for damage to the non-growth surface that can occur with traditional plasma or wet etching methods, which often lack perfect selectivity between the polymer and underlying materials. Second, the bottom-up removal mechanism ensures complete polymer elimination without leaving residues that could affect subsequent processing steps or device performance. Third, the low-temperature process may preserve the integrity of temperature-sensitive materials and prevent unwanted diffusion or intermixing in multi-material structures. Fourth, the process may avoid the use of harsh chemicals or aggressive plasma conditions that may introduce contamination or cause surface roughening. Additionally, the catalytic nature of the process provides inherent selectivity, as the polymer removal occurs preferentially at the catalytic interface, allowing for precise pattern formation without the need for additional masking steps or complex etch chemistries. Moreover, the polymer layer may function as a sacrificial material, making the process highly tolerant of polymer defects. In various embodiments, even if the polymer layer contains imperfections such as pinholes, thickness variations, or compositional non-uniformities, these defects do not propagate to the final structure because the polymer is completely removed during the catalytic oxidation step. This defect tolerance may enhance manufacturing yield and reduce the stringent quality requirements for the polymer deposition step, making the overall process more practical for high-volume semiconductor manufacturing.

FIG. 1G illustrates a cross-sectional view of the substrate 100 after completion of the catalytic polymer removal process. In various embodiments, the polymer layer 108 may be completely removed, exposing the catalytic surface 150 of the first region 106.

The exposed catalytic surface 150 may be free of polymer residues due to the efficient bottom-up removal mechanism facilitated by the catalytic polymer removal process. Clean exposure of the catalytic surface 150 may provide a foundation for subsequent processing steps, such as selective material deposition or contact formation.

In various embodiments, the catalytic surface 150 may retain its catalytic properties after polymer removal, or it may undergo surface modifications during the removal process that alter its chemical or physical properties. These surface modifications can be controlled through careful selection of polymer removal parameters, such as temperature, oxygen concentration, and annealing time, to achieve desired surface conditions for subsequent processing steps.

FIG. 1H illustrates a cross-sectional view of an etch stop layer deposition process, in accordance with an embodiment. In various embodiments, an etch stop layer 112 may be disposed over both the first region 106 and the coating layer 110, forming a continuous protective film across the substrate surface. In various embodiments, the etch stop layer 112 may serve to protect the underlying structures from damage during subsequent etching processes used to pattern an overlying dielectric layer.

In various embodiments, the etch stop layer 112 may comprise silicon carbonitride (SiCN), silicon oxycarbide (SiOC), silicon oxycarbonitride (SiOCN), aluminum oxycarbonitride (AlOCNₓ), or combinations thereof. The etch stop layer 112 may exhibit high etch selectivity relative to common dielectric materials, enabling precise control during subsequent patterning operations. In one or more embodiments, the etch stop layer 112 may be deposited using physical vapor deposition (PVD), chemical vapor deposition (CVD), atomic layer deposition (ALD), or other conformal deposition techniques that provide uniform coverage across the substrate topography. The thickness of the etch stop layer 112 may range from 2 nanometers to 50 nanometers, with the specific thickness selected based on etch selectivity requirements and overall device integration considerations.

FIG. 1I illustrates a cross-sectional view of a dielectric deposition process after forming the etch stop layer 112. A dielectric layer 114 may be disposed over the etch stop layer 112, providing electrical isolation and protection for the underlying structures.

In various embodiments, the dielectric layer 114 may comprise silicon dioxide (SiO₂), silicon nitride (SiN), silicon oxynitride (SiON), or low-k dielectric materials such as carbon-doped silicon oxide, porous silica, or organic polymers. In one or more embodiments, the dielectric layer 114 may be deposited using techniques including chemical vapor deposition (CVD), atomic layer deposition (ALD), spin-on deposition, or physical vapor deposition (PVD).

The combination of the etch stop layer 112 and dielectric layer 114 enables subsequent patterning operations to form vias, trenches, or other structures in the dielectric layer 114 while protecting the underlying first region 106 and coating layer 110 from damage. In various embodiments, during subsequent etching processes, the etch chemistry may be selected to have high selectivity between the dielectric layer 114 and the etch stop layer 112, allowing the etch to effectively stop at the etch stop layer 112. In some embodiments, a second, different etch chemistry may then be used to selectively remove portions of the etch stop layer 112 without damaging the underlying structures, enabling precise contact formation to the first region 106.

In various embodiments, following the patterning and etching of the dielectric layer 114 and selective removal of the etch stop layer 112 in contact regions, a conformal metal liner may be deposited over the patterned structure. In various embodiments, the conformal metal liner may comprise titanium (Ti), titanium nitride (TiN), tantalum (Ta), tantalum nitride (TaN), or combinations thereof. The conformal metal liner may be deposited using physical vapor deposition (PVD), atomic layer deposition (ALD), or chemical vapor deposition (CVD). In one or more embodiments, following the liner deposition, a top metal plug may be formed by depositing a conductive fill material such as tungsten (W), copper (Cu), or cobalt (Co). The deposition of top metal plug may be performed using electroplating, chemical vapor deposition, or physical vapor deposition techniques, with the specific approach selected based on feature dimensions and material requirements. The conformal metal liner and plug structure may create reliable electrical connections to the selectively deposited regions formed through the catalytic polymer removal process.

FIGS. 2A-2I illustrate cross-sectional views of process steps for a variation of area selective processing using a catalytic metal cap, in accordance with one embodiment. Components and features in FIGS. 2A-2I that share reference numbers with those in FIGS. 1A-1I have corresponding structures and operations as previously described.

FIG. 2A illustrates a cross-sectional view of a substrate 200 loaded in a process chamber, in accordance with one embodiment. The substrate 200 may comprise a first region 206 with a metal surface 250 and the second region 104 with a non-catalytic surface 252. Both regions are disposed over the substrate layer 102 that provides structural support and may contain previously formed device structures.

In various embodiments, the first region 206 may comprise metals such as copper (Cu), aluminum (Al), tungsten (W), titanium (Ti), nickel (Ni), molybdenum (Mo), silver (Ag), gold (Au), cobalt (Co), or their alloys. Unlike the substrate 100 described in FIG. 1A, where the first region may possess catalytic properties, the metal surface 250 may comprise standard interconnect metals that do not necessarily exhibit catalytic activity for polymer growth or removal.

In FIG. 2B, a catalytic metal cap 202 may be disposed over the metal surface 250 of the first region 206, in accordance with one embodiment. The catalytic metal cap 202 may provide a catalytically active surface necessary for subsequent selective polymer deposition and removal while maintaining the bulk electrical properties of underlying metals.

In various embodiments, a process of disposing the catalytic metal cap 202 over the metal surface 250 may comprise multiple steps. Initially, a catalytic metal layer may be deposited over both the first region 206 and the second region 104, forming a blanket film across the entire substrate surface. This deposition may be performed using physical vapor deposition (PVD) methods such as sputtering, chemical vapor deposition (CVD), atomic layer deposition (ALD), or electrochemical deposition techniques. Following the blanket deposition, a mask layer may be formed over the catalytic metal layer using photolithographic techniques. The mask pattern defines the areas where the catalytic metal should remain. Subsequently, an etching process may be performed to remove the catalytic metal from undesired areas, particularly over the second region 104, while retaining it over the first region 206. The etching may utilize reactive ion etching (RIE), wet chemical etching, or other selective material removal techniques. After etching, the mask layer may be removed, leaving the catalytic metal cap 202 selectively disposed over the metal surface 250 of the first region 206.

The catalytic metal cap 202 may comprise materials similar to those described for the first region 106 in FIG. 1A, such as ruthenium (Ru), platinum (Pt), palladium (Pd), or cobalt (Co). These materials may exhibit catalytic properties for facilitating subsequent polymer growth or removal. In various embodiments, the catalytic metal cap 202 may be a thin layer with a thickness of 1 to 4 nanometers, which may be sufficient to provide the necessary catalytic properties while minimize material usage, thereby ensuring cost-effectiveness in manufacturing.

FIG. 2C illustrates an optional surface treatment process applied to the substrate 200. In some embodiments, a surface treatment material 20 may be selectively applied to the non-catalytic surface 252 of the second region 104. This surface treatment step is similar to that shown in FIG. 1B.

The surface treatment material 20 may comprise same materials and serve the same function as previously described with reference to the surface treatment material 10, enhancing selectivity by further inhibiting polymer growth on the non-catalytic surface 252 during subsequent processing steps. Alternative treatment methods including plasma, annealing, or optical treatments may also be employed as previously described.

In various embodiments, the surface treatment may be applied selectively to the non-catalytic surface 252 while leaving the catalytic metal cap 202 untreated, thereby maximizing the contrast between growth and non-growth surfaces for subsequent polymer deposition. This selective application maintains the catalytic properties of the catalytic metal cap 202 while modifying the surface chemistry of the non-catalytic region to resist polymer nucleation and growth.

FIG. 2D illustrates a cross-sectional view of a polymer deposition process, similar to the process described for FIG. 1C. In various embodiments, the polymer layer 108 may be selectively disposed over the catalytic metal cap 202, with minimal or no deposition on the non-catalytic surface 252. The polymer materials, deposition methods, and thickness considerations may be similar with those previously described for FIG. 1C, with the polymer selectively forming on the catalytic metal cap 202 rather than an embedded catalytic surface (e.g., the catalytic surface 150).

FIG. 2E shows the deposition of the coating layer 110 over both the polymer layer 108 and the second region 104, similar to the process described for FIG. 1D. The coating layer 110 may cover the entire substrate surface with dielectric or metallic materials using ALD, CVD, or PVD methods as previously detailed. The coating layer 110 may serve the same purpose as described with reference to FIG. 1D.

FIG. 2F illustrates the planarization of the coating layer 110 to expose a top surface of the polymer layer 108, similar to the process described with reference to FIG. 1E. The planarization methods, including CMP and various etching techniques, may follow the same processes and parameters described previously, creating a flat surface where the top surface of the polymer layer 108 and the remaining coating layer 110 may be coplanar.

FIG. 2G illustrates removal of the polymer layer 108 through an annealing process, similar to the processes described with reference to FIGS. 1F and 1G. The catalytic metal cap 202 may facilitate the conversion of oxygen-containing molecular to reactive species that remove the polymer from the bottom up, using the same catalytic oxidation process described previously. The annealing process may result in a clean exposure of the catalytic metal cap 202 with the coating layer 110 remaining intact over the second region 104.

FIG. 2H shows the deposition of the etch stop layer 112 over both the exposed catalytic metal cap 202 and the coating layer 110, similar to the process described with reference to FIG. 1H. The etch stop layer materials and deposition methods may be similar with those described previously.

FIG. 2I illustrates the optional deposition of the dielectric layer 114 over the etch stop layer 112, similar to the process described with reference to FIG. 1I. The dielectric layer 114 may provide electrical isolation and protection using the same materials and deposition methods previously detailed. In various embodiments, the patterning of the dielectric layer 114 and subsequent deposition of conformal metal liner and top metal plug similar to those described with reference to FIG. 1I may follow the process in FIG. 2I.

FIGS. 3A-3H illustrate cross-sectional views of area selective processing to a three-dimensional structure, in accordance with one embodiment.

FIG. 3A illustrates a cross-sectional view of a substrate 300 comprising a three-dimensional (3D) structure. The substrate 300 differs from the planar substrates 100 and 200 of the previous embodiments in that it features topography with vertical and horizontal surfaces, representing advanced device architectures. In various embodiments, the substrate 300 may be parts of 3D structures such as FinFET structure, gate-all-around (GAA) transistor structure, 3D NAND flash memory structure, through-silicon via (TSV) structures, trench capacitors, deep trench isolation regions, or multi-level interconnect structures with varying aspect ratios and feature dimensions.

In one or more embodiments, the substrate 300 may comprise a substrate layer 302 that may comprise similar materials as the substrate layer 102 described in the previous embodiments. A first region 306 comprising a catalytic surface 352 and a second region 304 comprising a non-catalytic surface 350 may be disposed over a sidewall of the substrate layer 302. In various embodiments, the first region 306 and the second region 304 may comprise similar materials as the first region 106 and the second region 104 described with reference to FIG. 1A.

FIG. 3B illustrates an optional surface treatment process applied to the substrate 300. In various embodiments, a surface treatment material 30 may be selectively applied to the non-catalytic surface 350 of the second region 304, following similar processes as described for FIGS. 1B and 2C in previous embodiments. The surface treatment material 30 may serve to enhance selectivity by inhibiting polymer growth on the non-catalytic surfaces during subsequent processing steps. The material composition and application methods for the surface treatment material 30 may be similar with those previously described for the surface treatment materials 10 and 20, including silanes such as TMSDMA and alternative treatment approaches like plasma, annealing, or optical treatments.

FIG. 3C illustrates a polymer deposition process applied to the substrate 300. In one or more embodiments, a polymer layer 308 may be selectively disposed over the catalytic surface 352 of the first region 306, following similar principles and processes as described for FIGS. 1C in previous embodiments. The polymer layer 308 may comprise similar materials, deposition methods, and functional properties as the polymer layer 108 described with reference to FIG. 1C. The selective deposition results in polymer formation specifically on the catalytic surfaces of the 3D structure, including vertical sidewalls and recessed features containing catalytic materials.

FIG. 3D illustrates a coating layer deposition process applied to the substrate 300. In one or more embodiments, a coating layer 310 may be disposed over sidewalls of both the polymer layer 308 and the second region 304, following similar principles and processes as described for FIG. 1D in previous embodiments. The coating layer 310 may comprise similar dielectric or metallic materials, deposition methods, and functional properties as the coating layer 110 described with reference to FIG. 1D. The coating layer 310 may form a blanket film covering the 3D substrate surface, including topographical features such as sidewalls, corners, and recessed areas.

FIG. 3E illustrates an anisotropic etching process applied to the substrate 300. In one or more embodiments, an anisotropic etch process 32 may be employed to selectively remove portions of the coating layer 310 to expose the polymer layer 308, while maintaining the coating layer 310 on vertical surfaces. Unlike the planarization approach used in previous embodiments, the 3D structure of substrate 300 may necessitate directional etching to selectively remove material from horizontal surfaces while preserving material on sidewalls. In one or more embodiments, the anisotropic etch process 32 may utilize reactive ion etching (RIE) with carefully selected gas chemistries that provide high vertical-to-lateral etch ratios. Ion bombardment from the plasma may enhance material removal in the direction perpendicular to the substrate surface, creating a directional etching effect. Process parameters such as pressure, RF power, and gas flow rates may be optimized to achieve the desired etch profile.

FIG. 3F illustrates a polymer removal process applied to the substrate 300. In one or more embodiments, an annealing process similar to that described with reference to FIG. 1F may be applied to remove the polymer layer 308 from the 3D structure. The annealing process may be performed in an oxygen ambient at temperatures below 400 °C, facilitating the catalytic oxidation of the polymer layer. As described in previous embodiments, oxygen molecules may diffuse to the interface between the polymer layer 308 and the catalytic surface 352, where the catalytic surface facilitates the conversion of oxygen-containing molecular species to more reactive species that efficiently remove the polymer. The catalytic removal approach may be particularly beneficial for 3D structures as it provides gentle, selective polymer removal without damaging the underlying catalytic surfaces or the coating layer 310 that remains on vertical surfaces.

FIG. 3G illustrates an etch stop layer deposition process applied to the substrate 300. In one or more embodiments, an etch stop layer 312 may be disposed over the first region 306 and the coating layer 310, following similar principles and processes as described for FIG. 1H in previous embodiments. The etch stop layer 312 may comprise similar materials, deposition methods, and functional properties as the etch stop layer 112 described previously. In the context of the 3D structure, the etch stop layer deposition may create a conformal protective layer that follows the complex topography, including recessed areas and vertical surfaces where the coating layer 310 remains.

In FIG. 3H, a dielectric deposition process may be applied to the substrate 300. In one or more embodiments, a dielectric layer 320 may be disposed over the etch stop layer 312, following similar principles and processes as described for FIG. 1I in previous embodiments. The dielectric layer 320 may comprise similar dielectric materials, deposition methods, and functional properties as the dielectric layer 114 described earlier. The dielectric layer 320 may provide electrical isolation and protection for the metal structures within the 3D architecture.

While the processes described for the 3D structure in FIGS. 3A-3H follow principles similar to those detailed for the planar structure in FIGS. 1A-1I, it should be understood that the additional catalytic metal cap approach shown in FIGS. 2A-2I may also be applied to 3D structures. In various embodiments, conventional metal surfaces within a 3D architecture that lack inherent catalytic properties may be selectively capped with thin catalytic metal layers such as ruthenium, platinum, palladium, or cobalt. This approach combines the advantages of the catalytic metal cap method with the geometric complexity of 3D structures, enabling selective polymer deposition and subsequent processing on a wider range of base metal materials within advanced 3D device architectures. The catalytic metal cap may be selectively deposited on horizontal surfaces, vertical sidewalls, or within recessed features of the 3D structure, providing flexible implementation options for different device designs. The selective application of catalytic metal caps in 3D structures may further extend the applicability of the area selective processing technique to more complex device geometries and material systems.

FIG. 4 illustrates a flow diagram of a method for area selective processing using catalytic polymer removal, in accordance with one embodiment. The flow diagram may provide a sequential process flow that corresponds to the structural views illustrated in FIGS. 1A-1I or 3A-3H.

At block 402, a substrate may be received which may comprise a first region comprising a catalytic surface and a second region comprising a non-catalytic surface. The substrate may be the substrate 100 as described with reference to FIG. 1A, where the first region 106 comprises catalytic surface 150 and the second region 104 comprises non-catalytic surface 152. In various embodiments, the catalytic surface may comprise materials such as ruthenium, platinum, palladium, cobalt, or the like as described previously. In alternative embodiments, the substrate may be the substrate 300 as described in FIG. 3A.

At block 404, a polymer layer may be selectively disposed over the catalytic surface. The block 404 may correspond to the polymer deposition process described with reference to FIG. 1C, where polymer layer 108 is selectively formed on the catalytic surface 150. As previously detailed, the polymer layer may comprise materials such as nylon, polyaniline (PANI), polypyrrole (PPY), or polyethylenedioxythiophene (PEDOT), and may be deposited using molecular layer deposition or other selective deposition techniques. In some embodiments, a surface treatment as described with reference to FIG. 1B may be applied prior to disposing the polymer layer.

At block 406, a coating layer may be disposed over the polymer layer and the second region, where the coating layer may comprise dielectric or metallic materials. The process in this step may correspond to the coating layer deposition process shown in FIG. 1D, where coating layer 110 is deposited over both the polymer layer 108 and the second region 104. The coating materials and deposition methods may follow those previously described for FIG. 1D.

At block 408, a portion of the coating layer may be removed using planarization or etching process to expose the polymer layer, similar to the processes illustrated in FIG. 1E, where the coating layer 110 is planarized to expose the polymer layer 108. As previously detailed, process in block 408 may be accomplished through chemical mechanical planarization or various etching techniques. In alternative embodiments, the substrate may be a 3D structure and the coating layer may be removed using the anisotropic etching process as described in FIG. 3E.

At block 410, the polymer layer may be catalytically removed from bottom up by annealing the substrate. The process at block 410 may correspond to the polymer removal process shown in FIGS. 1F or 3F where oxygen molecules may diffuse to the catalytic interface and facilitate polymer removal through catalytic oxidation at temperatures below 400 °C. The catalytic oxidation process and its advantages have been detailed in the description of FIG. 1F.

At block 412, an etch stop layer may be disposed over the first region and the coating layer. This step may correspond to the etch stop layer deposition process illustrated in FIG. 1H, where the etch stop layer 112 is deposited over both the exposed catalytic surface 150 and the coating layer 110. The etch stop layer materials and deposition methods follow those previously described.

At block 414, a dielectric layer may be disposed over the etch stop layer. The process at this step may correspond to the dielectric deposition process shown in FIG. 1I, where dielectric layer 114 is deposited over the etch stop layer 112 to provide electrical isolation and protection. The dielectric materials and deposition methods follow those previously described for FIG. 1I.

FIG. 5 illustrates a flow diagram of a method for area selective processing using a deposited catalytic metal cap, in accordance with one embodiment. The flow diagram may provide a sequential process flow that corresponds to the structural views illustrated in FIGS. 2A-2I.

At block 502, a substrate may be loaded in a process chamber, where the substrate may comprise a first region comprising a metal surface and a second region comprising a non-catalytic surface. The substrate may be the substrate 200 as described with reference to FIG. 2A, where the first region 206 includes the metal surface 250 and the second region 104 includes the non-catalytic surface 252. As detailed in the description of FIG. 2A, the metal surface 250 may not necessarily exhibit catalytic properties.

At block 504, a catalytic metal cap may be selectively disposed over the metal surface of the first region. This may correspond to the catalytic metal cap deposition process described with reference to FIG. 2B, where the catalytic metal cap 202 is selectively formed on the metal surface 250.

At block 506, a polymer layer may be selectively disposed over the catalytic metal cap. The process at this step may correspond to the polymer deposition process shown in FIG. 2D, where the polymer layer 108 selectively forms on the catalytic metal cap 202. The polymer materials, deposition methods, and thickness considerations may follow those previously described for FIG. 2D. In some embodiments, a surface treatment as described with reference to FIG. 2C may be applied to the substrate prior to disposing the polymer layer.

At block 508, a coating layer may be disposed over the polymer layer and the second region. This step may correspond to the coating layer deposition process illustrated in FIG. 2E, where the coating layer 110 is deposited over both the polymer layer 108 and the second region 104. The coating materials and deposition methods may follow those previously described.

At block 510, a portion of the coating layer may be removed to expose the polymer layer. This step may correspond to the planarization process shown in FIG. 2F, where the coating layer 110 is planarized to expose the polymer layer 108. The planarization techniques follow those previously detailed for FIG. 2F. In some embodiments, the coating layered may be removed using various etching techniques as described with reference to FIG. 1E.

At block 512, the polymer layer may be catalytically removed by annealing the substrate. The process at this block may correspond to the polymer removal process illustrated in FIG. 2G, where the catalytic metal cap 202 may facilitate the oxidative removal of the polymer layer 108 through an annealing process below 400 °C. The catalytic removal mechanism and its advantages follow those previously described for FIG. 2G.

The process flow described in FIG. 5 demonstrates an alternative approach to area selective processing where catalytic properties are introduced through a selectively deposited metal cap rather than relying on inherently catalytic materials in the substrate. Additionally, while not explicitly shown in the figures, this catalytic metal cap approach may also be applied to 3D structures similar to those illustrated in FIGS. 3A-3H, providing versatility across both planar and 3D device architectures.

While not explicitly illustrated in FIGS. 1A-5, the area selective processing may include several additional steps that are integral to successful implementation in semiconductor manufacturing environments. Between the major process steps shown in the figures, substrate cleaning operations may be performed to remove potential contaminants that could affect selectivity or film quality. These cleaning steps may include wet chemical treatments, plasma cleaning, or in-situ thermal desorption processes. Purging operations may be conducted between processing steps to remove residual precursors or byproducts, preventing cross-contamination and undesired reactions. In multi-chamber processing systems, substrate transfer operations occur between chambers optimized for different process steps, with vacuum maintenance during transfers to prevent atmospheric exposure. Additional metrology steps may be integrated for in-line process monitoring, including thickness measurements, surface analysis, or defect inspection to ensure process quality. Conditioning steps for process chambers may also be performed periodically to maintain consistent process performance, particularly for polymer deposition and removal steps where chamber wall conditions can influence process results. These supplementary operations, while not depicted in the process flow diagrams, are essential for achieving the high yield and reliability required for semiconductor device manufacturing.

FIG. 6 illustrates a schematic diagram of an integrated system 600 for in-situ processing of area selective deposition and removal as described in FIGS. 1A-5, in accordance with an embodiment. The system 600 may comprise multiple specialized process modules arranged around a transfer module 601, enabling the sequential processing steps described in FIGS. 1A-5 without breaking vacuum conditions.

In various embodiments, the transfer module 601 may serve as a central hub of the system 600 and be configured to maintain vacuum conditions throughout substrate processing. The transfer module 601 may be coupled to various process modules and facilitate substrate movement between them while preventing atmospheric exposure that could introduce contamination or oxidation of sensitive surfaces. The transfer module 601 may be include a larger chamber than the chamber of the different modules and include mechanical drive systems to transfer the substrate from one chamber to another chamber without breaking vacuum.

In one or more embodiments, a surface treatment module 602 may be coupled to the transfer module 601. The surface treatment module 602 includes a chamber for processing a substrate and configured to apply a surface treatment material to the substrate as described in FIGS. 1B, 2C and 3B. The surface treatment module 602 may deliver materials such as trimethylsilyldimethylamine (TMSDMA) or other silane compounds to selectively treat non-catalytic surfaces. The surface treatment module 602 may include a wafer stage 620 for supporting the substrate during processing and a gate valve 622 that isolates the module from the transfer module 601 when closed. In alternative embodiments, the surface treatment module 602 may be configured to perform other surface treatment processes like plasma, annealing, or optical treatments as described with reference to FIG. 1B.

In various embodiments, a metal cap module 604 may be coupled to the transfer module 601. The metal cap module 604 includes a chamber and configured to deposit a catalytic metal cap on the substrate as described in FIG. 2B. The metal cap module 604 enables the selective deposition of thin catalytic metal layers such as ruthenium, platinum, palladium, or cobalt on conventional metal surfaces, expanding the applicability of the area selective deposition technique to a broader range of base materials.

In various embodiments, a substrate preparation module 606 may be coupled to the transfer module 601 and configured to prepare the substrate prior to processing in other modules. In one or more embodiments, the substrate preparation module 606 may perform various conditioning processes including surface cleaning to remove contaminants, surface activation to enhance reactivity, surface passivation to protect specific regions, and surface modification to alter chemical properties. These preparation steps, while not explicitly shown in FIGS. 1A-5, may improve performance in subsequent processing steps.

In one or more embodiments, a polymer deposition module 608 may be coupled to the transfer module 601. The polymer deposition module 608 may include a chamber for supporting the substrate and configured to selectively deposit a polymer layer on catalytic surfaces as described in FIGS. 1C, 2D and 3C. The polymer deposition module 608 may include inlets and outlets for the deposition gases described above. The polymer deposition module 608 may enable the selective formation of polymers such as polyaniline, polypyrrole, or polyethylenedioxythiophene through molecular layer deposition or other techniques previously detailed.

In various embodiments, a planarization module 610 may be coupled to the transfer module 601 and configured to planarize the substrate as described in FIGS. 1E and 2F. In some embodiments, the system 600 may also comprise an etching module coupled to the transfer module 601 and configured to selectively remove materials from the substrate as described in FIGS. 1E and 2F. In some embodiments, the etching module may be configured to apply anisotropic etching processing on the 3D structures as described with reference to FIG. 3E.

In one or more embodiments, an annealing module 612 may be coupled to the transfer module 601 and configured to remove the polymer layer from the substrate through catalytic oxidation as described in FIGS. 1F, 2G and 3F. The annealing module 612 may provide controlled temperature and atmospheric conditions for the gentle, selective removal of polymer materials.

In various embodiments, the system 600 may also comprise a load module 611 coupled to the transfer module 601, which may serve as an interface between the manufacturing environment and the vacuum processing system. The load module 611 may comprise a load lock module 630 configured to transition the substrate between atmospheric pressure and vacuum pressure, an aligner 650 configured to precisely position the substrate for processing, a wafer carrier 640 configured to hold wafers securely in a controlled environment, and a transport apparatus 660 configured to move the substrate between the various components of the system 600.

In one or more embodiments, a controller 621 may be operatively coupled to all modules of the system 600 and configured to coordinate substrate movement between modules and control process parameters in each module according to predetermined process recipes. In various embodiments, the controller 621 may comprise a central processing unit (CPU) that executes process control algorithms and coordinates operations across all modules. The CPU may be implemented as a single processor or a multi-core processor system with dedicated processing capabilities for different control functions. The controller 621 may comprise a memory system to support the CPU in storing both operational parameters and process instructions. The memory system may comprise non-volatile memory components such as flash memory or solid-state drives that store process recipes, calibration data, and system configuration information, as well as volatile random-access memory (RAM) for runtime data processing. In one or more embodiments, the memory system may store instructions for the controller 621 to automatically execute the process flows described in FIGS. 4 and 5, ensuring consistent and repeatable results.

In various embodiments, each process module may be equipped with the wafer stage 620 for supporting the substrate during processing and the gate valve 622 that isolates the module from the transfer module 601 or the load module 611 when closed. This configuration may allow maintenance or operation on individual modules without compromising the vacuum integrity of the entire system.

The integrated system 600 may enable complete in-situ processing for area selective processing using catalytic polymer removal, eliminating exposure to atmospheric conditions between process steps and thereby reducing contamination risks and enhancing process control. The system architecture may enable the implementation of both the embedded catalyst approach described in FIGS. 1A-1I and the catalytic metal cap approach illustrated in FIGS. 2A-2I, as well as their application to 3D structures as shown in FIGS. 3A-3H.

While the inventive aspects are described primarily in the context of semiconductor interconnect fabrication, it should also be appreciated that these inventive aspects may also apply to other semiconductor manufacturing processes and applications. In particular, aspects of this disclosure may similarly apply to memory device fabrication, transistor gate formation, and various three-dimensional device architectures.

In particular, aspects of this disclosure may similarly apply to three-dimensional NAND flash memory fabrication where selective deposition can be utilized for channel formation and wordline structures. The catalytic polymer approach may also be beneficial in FinFET and gate-all-around transistor manufacturing where precise material placement is critical. Additionally, the techniques described may be applicable to advanced packaging technologies where selective deposition can improve alignment and reduce processing steps for through-silicon vias and redistribution layers.

Example embodiments of the invention are described below. Other embodiments can also be understood from the entirety of the specification as well as the claims filed herein.

Example 1. A method for processing a substrate, the method including: providing a substrate including a first region and a second region, where the first region includes a catalytic surface and the second region includes a non-catalytic surface; forming a polymer layer selectively over the catalytic surface of the first region; forming a coating layer over the polymer layer and the second region; planarizing the coating layer to expose the polymer layer; and removing the polymer layer by annealing the substrate.

Example 2. The method of example 1, where the catalytic surface includes ruthenium, platinum, palladium, or cobalt.

Example 3. The method of one of examples 1 or 2, where the polymer layer includes nylon, polyaniline (PANI), polypyrrole (PPY), or polyethylenedioxythiophene (PEDOT).

Example 4. The method of one of examples 1 to 3, where the polymer layer is selectively deposited using molecular layer deposition (MLD) method.

Example 5. The method of one of examples 1 to 4, further including treating the non-catalytic surface with a surface treatment material before selectively disposing the polymer layer.

Example 6. The method of one of examples 1 to 5, where the surface treatment material includes phosphonic, carboxyllic, amine, or silane inhibitor molecules including includes trimethylsilyldimethylamine (TMSDMA).

Example 7. The method of one of examples 1 to 6, where the coating layer includes dielectric or metallic materials.

Example 8. A method for processing a substrate, the method including: loading a substrate in a process chamber, the substrate includes a first region including a metal surface and a second region including a non-catalytic surface; forming a catalytic metal cap over the metal surface of the first region; depositing a polymer layer selectively over the catalytic metal cap; forming a coating layer over the polymer layer and the second region; planarizing the coating layer to expose the polymer layer; and removing the polymer layer by annealing the substrate.

Example 9. The method of example 8, where forming the catalytic metal cap includes: forming a catalytic metal layer over the first and the second regions; and etching the catalytic metal layer through a pattern of a mask layer to form the catalytic metal cap.

Example 10. The method of one of examples 8 or 9, where removing the polymer layer includes annealing at a temperature less than 400 °C in an oxygen ambient.

Example 11. The method of one of examples 8 to 10, where planarizing the coating layer includes chemical mechanical polishing (CMP) process, etch back, or a combination of thereof.

Example 12. The method of one of examples 8 to 11, where the catalytic metal cap includes ruthenium, platinum, palladium, or cobalt.

Example 13. The method of one of examples 8 to 12, where the polymer layer includes nylon, polyaniline (PANI), polypyrrole (PPY), or polyethylenedioxythiophene (PEDOT).

Example 14. The method of one of examples 8 to 13, further including treating the non-catalytic surface with a surface treatment material before selectively depositing the polymer layer, where the surface treatment material includes phosphonic, carboxyllic, amine, or silane inhibitor molecules including trimethylsilyldimethylamine (TMSDMA).

Example 15. A system for processing a substrate, the system including: a transfer module configured to maintain vacuum conditions; a surface treatment module coupled to the transfer module and configured to apply a surface treatment material to a substrate; a metal cap module coupled to the transfer module and configured to form a catalytic metal cap on the substrate; a polymer deposition module coupled to the transfer module and configured to selectively deposit a polymer layer on the catalytic metal cap; a planarization module coupled to the transfer module and configured to planarize the substrate; and an annealing module coupled to the transfer module and configured to remove the polymer layer from the substrate.

Example 16. The system of example 15, further including a substrate preparation module coupled to the transfer module and configured to prepare the substrate prior to processing in other modules, the substrate preparation module configured to perform at least one of surface cleaning, surface activation, surface passivation, and surface modification.

Example 17. The system of one of examples 15 or 16, further including an etching module coupled to the transfer module and configured to selectively remove materials from the substrate.

Example 18. The system of one of examples 15 to 17, where the surface treatment material includes phosphonic, carboxyllic, amine, or silane inhibitor molecules including trimethylsilyldimethylamine (TMSDMA).

Example 19. The system of one of examples 15 to 18, further including a load module coupled to the transfer module, the load module including: a load lock module configured to transition the substrate between atmospheric pressure and vacuum pressure; an aligner configured to precisely position the substrate for processing; a wafer carrier configured to hold wafers securely and safely in a controlled environment; and a transport apparatus configured to move the substrate between the wafer carrier, the aligner, the load lock module, and the transfer module.

Example 20. The system of one of examples 15 to 19, further including a controller coupled to the transfer module and the load module and configured to coordinate substrate movement between modules and control process parameters in each module according to a predetermined process recipe.

While the inventive aspects are described primarily in the context of semiconductor fabrication, it should also be appreciated that these inventive aspects may also apply to other manufacturing processes and applications using selective deposition of organic materials.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-6 may be combined in further embodiments. It is therefore intended that the appended claims encompass any such modifications or embodiments.

What is claimed is:

1. A method for processing a substrate, the method comprising:
providing a substrate comprising a first region and a second region, wherein the first region comprises a catalytic surface and the second region comprises a non-catalytic surface;
forming a polymer layer selectively over the catalytic surface of the first region;
forming a coating layer over the polymer layer and the second region;
planarizing the coating layer to expose the polymer layer; and
removing the polymer layer by annealing the substrate.

2. The method of claim 1, wherein the catalytic surface comprises ruthenium, platinum, palladium, or cobalt.

3. The method of claim 1, wherein the polymer layer comprises nylon, polyaniline (PANI), polypyrrole (PPY), or polyethylenedioxythiophene (PEDOT).

4. The method of claim 1, wherein the polymer layer is selectively deposited using molecular layer deposition (MLD) method.

5. The method of claim 1, further comprising treating the non-catalytic surface with a surface treatment material before selectively disposing the polymer layer.

6. The method of claim 5, wherein the surface treatment material comprises phosphonic, carboxyllic, amine, or silane inhibitor molecules comprising trimethylsilyldimethylamine (TMSDMA).

7. The method of claim 1, wherein the coating layer comprises dielectric or metallic materials.

8. A method for processing a substrate, the method comprising:
loading a substrate in a process chamber, the substrate comprises a first region comprising a metal surface and a second region comprising a non-catalytic surface;
forming a catalytic metal cap over the metal surface of the first region;
depositing a polymer layer selectively over the catalytic metal cap;
forming a coating layer over the polymer layer and the second region;
planarizing the coating layer to expose the polymer layer; and
removing the polymer layer by annealing the substrate.

9. The method of claim 8, wherein forming the catalytic metal cap comprises:
forming a catalytic metal layer over the first and the second regions; and
etching the catalytic metal layer through a pattern of a mask layer to form the catalytic metal cap.

10. The method of claim 8, wherein removing the polymer layer comprises annealing at a temperature less than 400 °C in an oxygen ambient.

11. The method of claim 8, wherein planarizing the coating layer comprises chemical mechanical polishing (CMP) process, etch back, or a combination of thereof.

12. The method of claim 8, wherein the catalytic metal cap comprises ruthenium, platinum, palladium, or cobalt.

13. The method of claim 8, wherein the polymer layer comprises nylon, polyaniline (PANI), polypyrrole (PPY), or polyethylenedioxythiophene (PEDOT).

14. The method of claim 8, further comprising treating the non-catalytic surface with a surface treatment material before selectively depositing the polymer layer, wherein the surface treatment material comprises phosphonic, carboxyllic, amine, or silane inhibitor molecules comprising trimethylsilyldimethylamine (TMSDMA).

15. A system for processing a substrate, the system comprising:
a transfer module configured to maintain vacuum conditions;
a surface treatment module coupled to the transfer module and configured to apply a surface treatment material to a substrate;
a metal cap module coupled to the transfer module and configured to form a catalytic metal cap on the substrate;
a polymer deposition module coupled to the transfer module and configured to selectively deposit a polymer layer on the catalytic metal cap;
a planarization module coupled to the transfer module and configured to planarize the substrate; and
an annealing module coupled to the transfer module and configured to remove the polymer layer from the substrate.

16. The system of claim 15, further comprising a substrate preparation module coupled to the transfer module and configured to prepare the substrate prior to processing in other modules, the substrate preparation module configured to perform at least one of surface cleaning, surface activation, surface passivation, and surface modification.

17. The system of claim 15, further comprising an etching module coupled to the transfer module and configured to selectively remove materials from the substrate.

18. The system of claim 15, wherein the surface treatment material comprises phosphonic, carboxyllic, amine, or silane inhibitor molecules comprising trimethylsilyldimethylamine (TMSDMA).

19. The system of claim 15, further comprising a load module coupled to the transfer module, the load module comprising:
a load lock module configured to transition the substrate between atmospheric pressure and vacuum pressure;
an aligner configured to precisely position the substrate for processing;
a wafer carrier configured to hold wafers securely and safely in a controlled environment; and
a transport apparatus configured to move the substrate between the wafer carrier, the aligner, the load lock module, and the transfer module.

20. The system of claim 19, further comprising a controller coupled to the transfer module and the load module and configured to coordinate substrate movement between modules and control process parameters in each module according to a predetermined process recipe.
